(19) United States
(12) Patent Application Publication
(10) Pub. No.: US 2002/0113273 A1
(43) Pub. Date: Aug. 22, 2002

(54) Semiconductor device having contact plug and method for manufacturing the same

(75) Inventors: Yoo-Sang Hwang, Kyungki-do (KR); Su-Jin Ahn, Seoul (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-city (KR)

(21) Appl. No.: 09/955,388

(22) Filed: Sep. 17, 2001

(30) Foreign Application Priority Data
Feb. 22, 2001 (KR) 01-9000

(51) Int. Cl. H01L 29/76; H01L 29/94; H01L 31/062; H01L 31/113; H01L 31/119

(52) U.S. Cl. 257/374

(57) ABSTRACT

A semiconductor device having a contact plug and a method for manufacturing the same are provided. A diffusion barrier layer is formed on a semiconductor substrate on which an insulating layer having a contact hole has been formed. A first metal layer is formed on the diffusion barrier layer filling the contact hole, and the first metal layer is etched back to a predetermined depth to expose a void in the first metal layer, if any, thereby forming a first sub-plug. A second metal layer is formed on the semiconductor substrate on which the first sub-plug has been formed. The second metal layer is polished so as to expose the top surface of the diffusion barrier layer on the insulating layer. As a result, a second sub-plug in the contact hole is formed. Therefore, a contact plug comprising the first and second sub-plugs and having strong resistance to particles generated in chemical and mechanical polishing (CMP) has been formed in the contact hole without a void or crack.

### BACKGROUND OF THE INVENTION

1. Field of the Invention

The present invention relates to a semiconductor device, and more particularly, to a semiconductor device having a contact plug and a method for manufacturing the same.

2. Description of the Related Art

A contact plug formed within an insulating layer between a semiconductor substrate and a bit line or a storage electrode has been used for connecting an active region on the semiconductor substrate and the bit line, for connecting an active region on a semiconductor substrate and a storage electrode of a capacitor, and for connecting an active region of a peripheral circuit or a gate electrode and a bit line. There are two different types of techniques for forming a contact plug, one technique using tungsten and the other technique using titanium nitride. In the case of using tungsten having a strong tensile strength to form a contact plug, a void may be formed in the contact hole. In addition, after the contact hole is filled with tungsten, chemical mechanical polishing (CMP) and cleaning processes are performed to complete the formation of a contact plug. At this time, tungsten may be melted or dissolved by a cleaner used in the cleaning process. Thus, particles generated in the chemical mechanical polishing process may not be completely removed in the cleaning process.

On the other hand, a titanium nitride layer has superior step coverage compared with tungsten and thus, a void can be prevented in a contact plug made of titanium nitride. Also, the problem occurring in a contact plug made of tungsten where tungsten is melted or dissolved by a cleaner in the cleaning process is not observed in a contact plug made of titanium nitride. For this reason, it is possible to sufficiently remove particles generated in a chemical mechanical polishing process by intensively performing a cleaning process. In addition, in the case of forming a contact plug of titanium nitride, an adhesive layer used for enhancing adhesive strength between tungsten and an insulating layer containing a silicon component, that is, a titanium nitride layer is not required in depositing a tungsten bit line in contact with the contact plug because the titanium nitride layer used in the formation of the contact plug can act as an adhesive layer. Thus, the thickness of a bit line structure including a bit line and an adhesive layer can be reduced. Therefore, it is possible to prevent the process of etching back the bit line structure from being excessively performed, thereby minimizing the degree by which an diffusion barrier layer formed in the contact plug is recessed. However, if the titanium nitride layer is deposited to a thickness of 1000 Å or greater, cracks may occur in the contact plug due to stress.

### SUMMARY OF THE INVENTION

To solve the above problems, the present invention provides a semiconductor device including a contact plug that has substantially no void or crack and a method for manufacturing the same.

Also, the present invention provides a semiconductor device including a contact plug which has no void or crack and has strong resistance to particles generated in chemical and mechanical polishing and a method for manufacturing the same.

Accordingly, a semiconductor device in accordance with one embodiment of the present invention includes a semiconductor substrate; an insulating layer formed on the semiconductor substrate and having a contact hole; an diffusion barrier layer formed on the insulating layer and the contact hole; and a contact plug which comprises a first sub-plug filling the contact hole and formed to have a first height relative to the bottom of the contact hole and a second sub-plug formed to extend from the top surface of the first sub-plug to the top of the contact hole.

The first sub-plug is formed of tungsten and the second sub-plug is formed of one of a titanium nitride layer and tungsten. In the case of forming the second sub-plug of a titanium nitride layer, it is preferable that the titanium nitride layer has a thickness no greater than 1000 Å, particularly, about 500 Å. The diffusion barrier layer is formed of titanium/titanium nitride.

In accordance with another embodiment of the present invention, a method for manufacturing a semiconductor device includes preparing a semiconductor substrate; forming an insulating layer having a contact hole on the semiconductor substrate; forming an diffusion barrier layer on the insulating layer and the contact hole; and forming a plug in the contact hole by forming a first sub-plug with a first height relative the bottom of the contact hole and forming a second sub-plug extending from the top surface of the first sub-plug to the top of the contact hole.

In an example method for forming a first sub-plug, a first metal layer is formed on the insulating layer having the contact hole and is etched back to a predetermined depth to which a void which may be formed in the first metal layer reaches. The first sub-plug is formed of tungsten. In an example method for forming a second sub-plug, a second metal layer is formed on the semiconductor substrate on which the first sub-plug has been formed and is polished so as to expose the top surface of the diffusion barrier layer. The second sub-plug is formed of one of tungsten and a titanium nitride layer. The second sub-plug has a thickness no greater than 1000 Å.

In accordance with one aspect of the present invention, a semiconductor device comprises a semiconductor substrate; an insulating layer formed on the semiconductor substrate and having a contact hole therethrough; a diffusion barrier layer formed on a surface of the insulating layer and on surfaces within the contact hole; and a contact plug which comprises a first sub-plug that fills a lower portion of the contact hole and a second sub-plug that fills an upper portion of the contact hole on the first sub-plug.

In accordance with another aspect of the present invention, a method for manufacturing a semiconductor device comprises forming an insulating layer having a contact hole therethrough on a semiconductor substrate; forming a diffusion barrier layer on a surface of the insulating layer and on surfaces within the contact hole; and forming a plug in the contact hole by forming a first sub-plug that fills a lower portion of the contact hole and forming a second sub-plug that fills an upper portion of the contact hole on the first sub-plug.

### BRIEF DESCRIPTION OF THE DRAWINGS

The above objects and advantages of the present invention will become more apparent by describing in detail a preferred embodiment thereof with reference to the attached drawings in which:

FIGS. 1 through 4 are cross-sectional diagrams illustrating a method for manufacturing a contact plug according to the present invention.

### DETAILED DESCRIPTION OF THE INVENTION

The present invention now will be described more fully with reference to the accompanying drawings, in which preferred embodiments of the invention are shown.

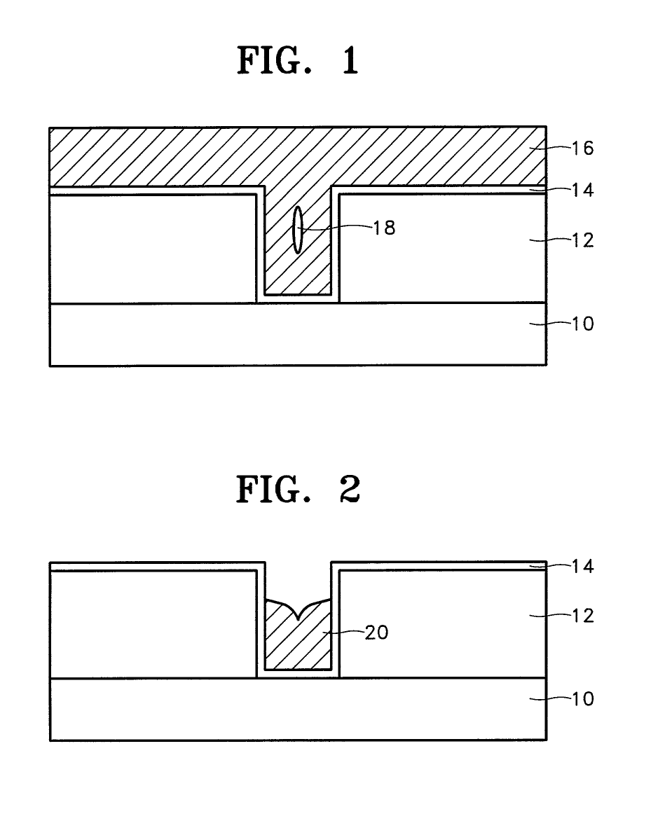

Referring to the embodiment shown in FIG. 1, an insulating layer 12 is formed on a semiconductor substrate 10. A contact hole is formed by etching a predetermined portion of the insulating layer 12 to expose a region of an active region of the semiconductor substrate 10. A diffusion barrier layer 14 is formed on the insulating layer 12 and at the sidewalls and bottom surface of the contact hole. The diffusion barrier layer 14 comprises a titanium/titanium nitride layer 14. Next, a first metal layer 16, that is, a tungsten layer is formed on the diffusion barrier layer 14 filling the contact hole. A void 18 is formed in the first metal layer 16 filled in the contact hole. Here, the first metal layer 16 is a tungsten layer; however, any metal layer capable of generating a void in the contact hole may be used as the first metal layer 16 instead of the tungsten layer.

Referring to FIG. 2, the first metal layer 16 is etched back to a predetermined depth to which the void 18 of FIG. 1 reaches, thereby forming a first sub-plug having a first height relative to the bottom of the contact hole.

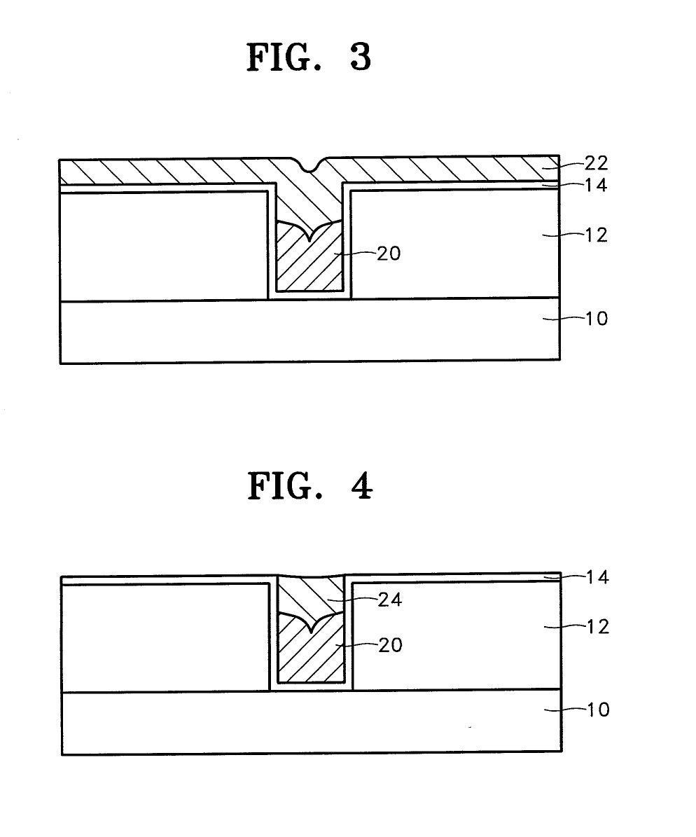

Referring to FIG. 3, a second metal layer 22 is formed by atomic layer deposition on the semiconductor substrate 10 on which the first sub-plug 20 has been formed. Any material that resists melting or dissolving in a chemical mechanical polishing or cleaning process can be used as the second metal layer 22. The material of the second metal layer 22 may be the same as or different from the first metal layer 16. Specifically, the second metal layer 22 may be a tungsten or titanium nitride layer. In the case of using a titanium nitride layer as the second metal layer 22, a cleaning process performed after the formation of a second sub-plug 24 can be intensively performed and thus, the second sub-plug can have strong resistance to particles generated in chemical mechanical polishing. In addition, in the case of using a titanium nitride layer as the second sub-plug 24, the second sub-plug is preferably deposited to a thickness of no greater than 1000 Å, specifically, a thickness of about 500 Å.

Referring to FIG. 4, the second sub-plug 24 is formed by performing a planarization process such as chemical mechanical polishing (CMP) on the second metal layer 22 of FIG. 3 so as to expose the top surface of the diffusion barrier layer 14. As a result, a contact plug comprising the first and second sub-plugs 20 and 24 has been formed in the contact hole.

The first metal layer 16 is etched back to a predetermined depth to which the void 18 reaches and thus, there is no void in the first sub-plug 20. If a material, which a cleaner used in a cleaning process subsequent to a chemical mechanical polishing process has difficulty melting, is used as the second metal layer 22, the cleaning process can be intensively performed. Therefore, it is possible to form a contact plug having strong resistance to particles generated in the chemical mechanical polishing process for formation of the contact plug. In the present invention, a titanium nitride layer is used for producing these effects. The upper part of the contact plug is formed of a titanium nitride layer, thereby minimizing the amount of time required in etching a bit line to be formed at the upper part of the contact plug and minimizing the degree by which the diffusion barrier layer within the contact hole is recessed.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A semiconductor device comprising:
a semiconductor substrate;
an insulating layer formed on the semiconductor substrate and having a contact hole therethrough;
a diffusion barrier layer formed on a surface of the insulating layer and on surfaces within the contact hole; and
a contact plug which comprises a first sub-plug that fills a lower portion of the contact hole and a second sub-plug that fills an upper portion of the contact hole on the first sub-plug.

2. The semiconductor device of claim 1, wherein the first sub-plug is formed of tungsten and the second sub-plug is formed of titanium nitride.

3. The semiconductor device of claim 2, wherein the titanium nitride is formed to a thickness of no greater than approximately 1000 Å.

4. The semiconductor device of claim 2, wherein the diffusion barrier layer is formed of titanium/titanium nitride.

5. A method for manufacturing a semiconductor device comprising:
forming an insulating layer having a contact hole therethrough on a semiconductor substrate;
forming a diffusion barrier layer on a surface of the insulating layer and on surfaces within the contact hole; and
forming a plug in the contact hole by forming a first sub-plug that fills a lower portion of the contact hole and forming a second sub-plug that fills an upper portion of the contact hole on the first sub-plug.

6. The method for manufacturing a semiconductor device of claim 5, wherein forming a first sub-plug comprises forming a first metal layer on the insulating layer having the contact hole therethrough and etching back the first metal layer to a predetermined depth to expose a void in the first metal layer, if any.

7. The method for manufacturing a semiconductor device of claim 5, wherein forming a second sub-plug comprises forming a second metal layer on the semiconductor substrate on which the first sub-plug has been formed and polishing the second metal layer so as to expose a top surface of the diffusion barrier layer on the insulating layer.

8. The method for manufacturing a semiconductor device of claim 6, wherein forming a second sub-plug comprises forming a second metal layer on the semiconductor substrate on which the first sub-plug has been formed and polishing the second metal layer so as to expose a top surface of the diffusion barrier layer on the insulating layer.

9. The method for manufacturing a semiconductor device of claim 5, wherein the first sub-plug is formed of tungsten.

10. The method for manufacturing a semiconductor device of claim 5, wherein the second sub-plug is formed of one of tungsten and titanium nitride.

11. The method for manufacturing a semiconductor device of claim 5, wherein the second sub-plug is formed to a thickness no greater than 1000 Å.

12. The method for manufacturing a semiconductor device of claim 5, wherein the diffusion barrier layer is formed of titanium/titanium nitride.
